(19) United States
(12) Patent Application Publication
(10) Pub. No.: US 2019/0352235 A1
(43) Pub. Date: Nov. 21, 2019

(54) CERAMIC-BASED TOUGHNESS-ENHANCED MATERIAL BASED ON SINGLE CRYSTAL SAPPHIRE FIBER AND PREPARATION METHOD THEREFOR

(71) Applicants: Research Institute of Tsinghua University in Shenzhen, Shenzhen (CN); Tsinghua Innovation Center in Dongguan, Dongguan (CN)

(72) Inventors: Renchen LIU, Shenzhen (CN); Shishan JI, Shenzhen (CN); Yan LIU, Shenzhen (CN); Qing MA, Shenzhen (CN); Shugang YAN, Shenzhen (CN); Xinguo WU, Shenzhen (CN)

(21) Appl. No.: 16/028,446

(22) Filed: Jul. 6, 2018

Related U.S. Application Data
(63) Continuation of application No. PCT/CN2018/087104, filed on May 16, 2018.

(51) Int. Cl. C04B 35/80; C04B 35/63; C04B 35/634; C04B 35/626; C04B 35/645

(52) U.S. Cl. CPC C04B 35/806; C04B 35/803; C04B 35/6303; C30B 29/20; C04B 35/63444; C04B 35/62655; C04B 35/645; C04B 35/63488

(57) ABSTRACT

A ceramic-based toughness-enhanced material includes the following starting materials by volume percentage: 92-96% ceramic substrate powder, 2-4% single crystal sapphire fiber, 0.3-0.4% ceramic substrate disperser, 0.6-0.7% single crystal sapphire fiber disperser and 3-5% sintering aid.

### CROSS-REFERENCE TO RELATED APPLICATIONS

The continuation application claims priority to Patent Application No. PCT/CN2018/087104, filed with the Chinese Patent Office on May 16, 2018, titled “CERAMIC-BASED TOUGHNESS-ENHANCED MATERIAL BASED ON SINGLE CRYSTAL SAPPHIRE FIBER AND PREPARATION METHOD THEREFOR”, the entire contents of which are incorporated herein by reference.

### TECHNICAL FIELD

Embodiments of the present disclosure relate to the technical field of ceramic materials, and in particular, relate to a ceramic-based toughness-enhanced material based on single crystal sapphire fiber, and a preparation method therefor.

### BACKGROUND

Ceramic materials, due to their excellent strength property, high modulus of elasticity, high wear resistance, power corrosion resistance and the like, have a good development prospect in the field of high-end materials. However, under restrictions of the structural features of the ceramic material, the brittleness of the ceramic material is high and the fracture toughness thereof is extremely low. This severely hinders the application of the ceramic material in various different fields. How to improve the toughness of the ceramic-based material is a hot development trend in the current fields of materials, and is a problem to be urgently solved or addressed.

The current theoretic study shows that the brittleness of the ceramic material is high due to the following reasons. In one aspect, the crystal structure of the ceramic material pertains to the corundum type, and is formed of strongly directional ion bonds and covalent bonds. Therefore, under an external force, plastic deformations due to crystal slips may nearly not occur. In another aspect, during preparation of the ceramic material, some defects or micro cracks may be present in the crystal grain or on the crystal interface. Under the effect of an external load, the stress may be concentrated at the tip of the cracks, and thus the toughness of the material is reduced and even brittle fracture may occur.

The single crystal sapphire fiber is a single crystal alumina whiskers having a specific aspect ratio, because the single crystal sapphire fiber has a high melting point, high strength, high wear resistance and high corrosion resistance. Therefore, the single crystal sapphire fiber is suitable for enhancing elements of ceramic, metal, plastic and rubber. After the metal is added into the single crystal sapphire whiskers, flexural modulus of elasticity, tensile strength, dimensional stability and thermal distortion temperature of the finished products may be significantly improved.

Traditionally, a technical solution of adding a single crystal sapphire fiber into a ceramic-based material is proposed to reduce the crack sources or reasonably control the expansion speed of the cracks, to improve the anti-crack expansion capabilities of the ceramic material and prevent concentration of the stress, so as to improve the toughness of the ceramic material.

### SUMMARY

An embodiments of the present disclosure provides a ceramic-based toughness enhanced material based on single crystal sapphire fiber comprises the following starting materials by volume percentage:

ceramic substrate powder 84-96%;

single crystal sapphire fiber 2-4%;

ceramic substrate disperser 0.3-0.4%;

single crystal sapphire fiber disperser 0.6-0.7%; and

sintering aid 3-5%.

Another embodiments of the present disclosure provides a preparation method for the ceramic-based toughness-enhanced material based on single crystal sapphire fiber comprises: weighing the ceramic substrate powder and the single crystal sapphire fiber; adding the ceramic substrate powder into a first reaction container, and adding the single crystal sapphire into a second reaction container; adding the ceramic substrate disperser into the first reaction container, and stirring at a high speed and carrying out ultrasonic treatment to obtain a uniformly dispersed first suspension; adding the single crystal sapphire fiber disperser into the second reaction container, and stirring at a high speed and carrying out ultrasonic treatment to obtain a uniformly dispersed second suspension; dropwise adding the second suspension into the first suspension, and stirring at a high speed such that the first suspension and the second suspension are sufficiently mixed to obtain a third suspension; vacuum filtering and drying the third suspension to obtain a mixed powder; and adding the mixed powder and the sintering aid into a graphite mold for hot-pressing sintering to obtain the ceramic-based toughness-enhanced material.

### BRIEF DESCRIPTION OF THE DRAWINGS

FIG. 1 is a flowchart illustrating a preparation method for a ceramic-based toughness-enhanced material based on single crystal sapphire fiber according to an embodiment of the present disclosure; and

FIG. 2 is a scanning electron micrograph of single crystal sapphire fiber according to an embodiment of the present disclosure.

### DETAILED DESCRIPTION

In order to make the objectives, technical solutions, and advantages of the present disclosure clearer, the present disclosure is further described in detail below by reference to the embodiments. It should be understood that the specific embodiments described herein are only intended to explain the present disclosure instead of limiting the present disclosure. In addition, technical features involved in various embodiments of the present disclosure described hereinafter may be combined as long as these technical features are not in conflict.

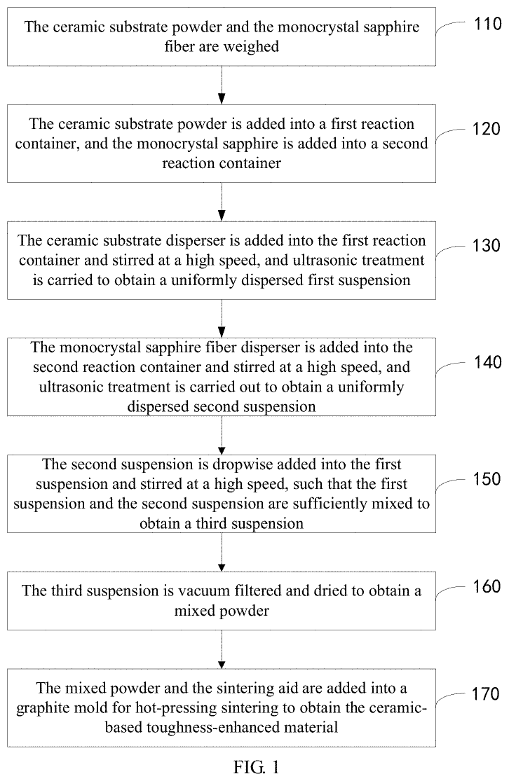

FIG. 1 illustrates a preparation method for a ceramic-based toughness-enhanced material based on single crystal sapphire fiber according to an embodiment of the present disclosure. As illustrated in FIG. 1, the method may comprise the following steps:

110: The ceramic substrate powder and the single crystal sapphire fiber are weighed.

The single crystal sapphire fiber is a single crystal alumina whiskers having a specific aspect ratio, because the single crystal sapphire fiber has a high melting point, high strength, high wear resistance and high corrosion resistance. Therefore, the single crystal sapphire fiber is suitable for enhancing elements of ceramic, metal, plastic and rubber. After the single crystal sapphire whiskers are added into a metal, flexural modulus of elasticity, tensile strength, dimensional stability and thermal distortion temperature of the finished products may be significantly improved. In this embodiment, the single crystal sapphire fiber may be prepared by means of Czochralski technique, Kyropoulos technique, Edge-defined Film-fed Growth (EFG) technique, heat exchange technique, temperature gradient technique, directional crystallization or the like.

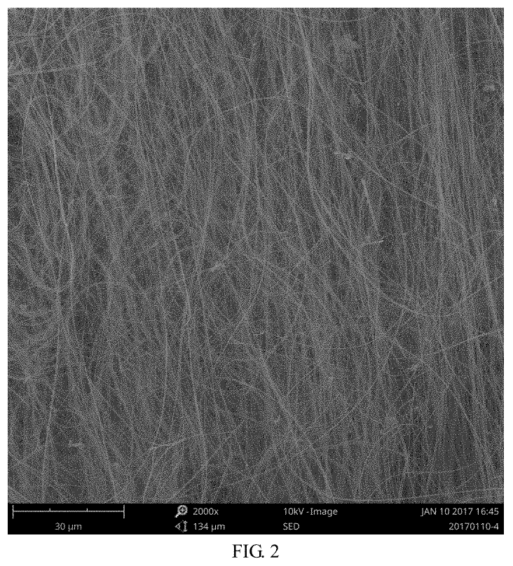

In this embodiment, the selected single crystal sapphire fiber is directly placed on a conductive adhesive for scanning electron microscope (SEM) testing. When the operating voltage is 10 KV and the amplification magnitude is 2000, the appearance of the obtained single crystal sapphire fiber is as illustrated in FIG. 2. As seen from FIG. 2, the single crystal sapphire fiber is uniformly distributed in a specified linear shape, and has a high molding ratio and a great aspect ratio.

The ceramic substrate powder may be specifically any suitable type of ceramic substrate. Preferably, magnesium oxide ceramic substrate powder, zirconium oxide ceramic substrate powder, or silicon carbide ceramic substrate powder may be selected as the ceramic substrate powder to prepare the ceramic substrate toughness-enhanced material.

120: The ceramic substrate powder is added into a first reaction container, and the single crystal sapphire is added into a second reaction container.

The first reaction container and the second reaction container may be specifically any type of container in which the corresponding stirring or ultrasonic operation may be carried out, including but not limited to glass containers.

The first reaction container and the second reaction container may have a corresponding capacity to accommodate the reaction requirements of the stirring operation and the ultrasonic operation of the ceramic substrate powder and the single crystal sapphire fiber.

130: The ceramic substrate disperser is added into the first reaction container and stirred at a high speed, and ultrasonic treatment is carried to obtain a uniformly dispersed first suspension.

The ceramic substrate disperser is a solvent which is used to make the ceramic substrate powder to sufficiently disperse to form a corresponding suspension. Any suitable type of disperser may be used as the ceramic substrate disperser. Specifically, polyethylene glycol (PEG) may be used as the ceramic substrate disperser.

140: The single crystal sapphire fiber disperser is added into the second reaction container and stirred at a high speed, and ultrasonic treatment is carried out to obtain a uniformly dispersed second suspension.

In this embodiment, the single crystal sapphire fiber and the ceramic substrate powder are respectively dispersed in two different reaction containers, such that the single crystal sapphire fiber and the ceramic substrate powder are sufficiently stirred in the suspension state, which ensures the hybrid effect of the phase-enhanced whiskers.

150: The second suspension is dropwise added into the first suspension and stirred at a high speed, such that the first suspension and the second suspension are sufficiently mixed to obtain a third suspension.

The above dropwise adding the suspension may be carried out manually adding or by a robot arm. In some embodiments, in the course of dropwise adding, the pH value of the third suspension may also be simultaneously tested and monitored, to prevent agglomeration or precipitation in the suspension.

160: The third suspension is vacuum filtered and dried to obtain a mixed powder.

After such operations as filtering, drying and the like are performed for the sufficiently mixed third suspension, powder that is the sufficiently mixed state is obtained as a synthesis basis for the final ceramic-based toughness-enhanced material.

170: The mixed powder and the sintering aid are added into a graphite mold for hot-pressing sintering to obtain the ceramic-based toughness-enhanced material.

Hot-pressing sintering refers to filling the dry powder into the mold and applying a pressure and heating the powder from a single axis direction, such that molding and sintering are completed simultaneously. The corresponding sintering aid is added into the graphite mold that is subjected to hot-pressing sintering, which achieves the effects of lowering the sintering temperature of the mixed powder, significantly improves the compact density of the material matrix and promotes the mass transfer and migration velocity between the ceramic substrate powder and the whiskers. In this way, the comprehensive mechanical properties of the material are improved.

In this embodiment, the ceramic-based toughness-enhanced material comprises the following starting materials by volume percentage: ceramic substrate powder 84-96%; single crystal sapphire fiber 2-4%; ceramic substrate disperser 0.3-0.4%; single crystal sapphire fiber disperser 0.6-0.7%; and sintering aid 3%-5%.

Since during the high temperature sintering process, the powder substrate is the mixed powder of the ceramic material and the whiskers, the sintering aid having a single component may not achieve the effect of sintering densification.

Therefore, in a preferred embodiment, the sintering aid is Al₂O₃—SiO₂—CaSO₄ nano powder composite sintering aid distributed in a network gel.

The network gel refers to a three-dimensional gel network structure formed by linkage of polymer chains. The sintering aid is subjected to barrier of the organic gel and is uniformly distributed in the three-dimensional network space. This better ensures uniform dispersing between the above nano powders, and reduces the probability of agglomeration of the above three powders.

In this embodiment, a ternary composite nano powder of Al₂O₃—SiO₂—CaSO₄ is used. This improves the mass transfer and migration velocity between the ceramic substrate powder and the whiskers during the sintering process, such that the prepared ceramic material has a better compact density.

Calcium sulfate is used as the sintering aid, and may not react with the ceramic substrate powder or the whiskers during the reaction. Addition of the calcium sulfate better improves the compact density of the sintered material, and achieves a better effect in use.

In the preparation method according to the embodiment of the present disclosure, the component ratio of the ceramic substrate powder to the single crystal sapphire fiber is adjusted, and the suitable sintering aid is added, such that a ceramic-based roughness-enhanced material having a good compact density and fracture toughness is prepared.

The single crystal sapphire fiber is uniformly distributed in the ceramic-based toughness-enhanced material, and vertically arranged along a direction, thereby forming a complete single crystal sapphire whisker grid.

Hereinafter, with reference to the specific examples, the preparation of the ceramic-based toughness-enhanced material based on single crystal sapphire fiber is described in detail.

### First Embodiment

Firstly, according to the volume percentage, the following starting material components were obtained: ceramic substrate powder 92%, single crystal sapphire fiber 4%, ceramic substrate disperser 0.3%, single crystal sapphire fiber disperse 0.7%, and sintering aid 3%.

Secondly, the ceramic substrate powder and the single crystal sapphire fiber were respectively added into a first glass reaction container and a second glass reaction container, to prepare a uniformly mixed suspension.

The ceramic substrate disperser was added into the first glass reaction container, stirred at a high speed for 3 to 5 minutes, and ultrasonically treated for 6 to 8 minutes to obtain a uniformly dispersed first suspension. In addition, the single crystal sapphire fiber disperse was added into the second glass reaction container, stirred at a high speed for 4 to 6 minutes, and ultrasonically treated for 6 to 8 minutes to obtain a uniformly dispersed second suspension.

Thirdly, the second suspension was dropwise added into the first suspension. During the dropwise addition of the second suspension, the first suspension and the second suspension were stirred at a high speed such that the two suspensions are sufficiently mixed to obtain a third suspension. The third suspension was made to stand still for 1 to 3 hours, and then the third suspension after standing still was vacuum filtered to obtain a precipitate.

The precipitate was dried at a temperature of 97° C. to 103° C. for at least 36 hours to obtain a dried mixed powder.

Finally, the mixed powder and a sintering aid (Al₂O₃—SiO₂—CaSO₄ ternary composite nano powder) was added into a graphite mold for hot-pressing sintering to obtain the ceramic-based toughness-enhanced material.

The hot-pressing sintering was carried out under a sintering temperature of 1800° C. to 2000° C., a heat preservation time of 30 to 50 minutes, and a sintering pressure of 30 to 35 MPa.

### Second Embodiment

Firstly, according to the volume percentage, the following starting material components were obtained: ceramic substrate powder 92%, single crystal sapphire fiber 3%, ceramic substrate disperser 0.4%, single crystal sapphire fiber disperse 0.6%, and sintering aid 4%.

Secondly, the ceramic substrate powder and the single crystal sapphire fiber were respectively added into a first glass reaction container and a second glass reaction container, to prepare a uniformly mixed suspension.

The ceramic substrate disperser was added into the first glass reaction container, stirred at a high speed for 3 to 5 minutes, and ultrasonically treated for 6 to 8 minutes to obtain a uniformly dispersed first suspension. In addition, the single crystal sapphire fiber disperse was added into the second glass reaction container, stirred at a high speed for 4 to 6 minutes, and ultrasonically treated for 6 to 8 minutes to obtain a uniformly dispersed second suspension.

Thirdly, the second suspension was dropwise added into the first suspension. During the dropwise addition of the second suspension, the first suspension and the second suspension were stirred at a high speed such that the two suspensions are sufficiently mixed to obtain a third suspension. The third suspension was made to stand still for 1 to 3 hours, and then the third suspension after standing still was vacuum filtered to obtain a precipitate.

The precipitate was dried at a temperature of 97° C. to 103° C. for at least 36 hours to obtain a dried mixed powder.

Finally, the mixed powder and a sintering aid ((Al₂O₃—SiO₂—CaSO₄ ternary composite nano powder) was added into a graphite mold for hot-pressing sintering to obtain the ceramic-based toughness-enhanced material.

The hot-pressing sintering was carried out under a sintering temperature of 1800° C. to 2000° C., a heat preservation time of 30 to 50 minutes, and a sintering pressure of 30 to 35 MPa.

### Third Embodiment

Firstly, according to the volume percentage, the following starting material components were obtained: ceramic substrate powder 92%, single crystal sapphire fiber 4%, ceramic substrate disperser 0.3%, single crystal sapphire fiber disperse 0.7%, and sintering aid 3%.

Secondly, the ceramic substrate powder and the single crystal sapphire fiber were respectively added into a first glass reaction container and a second glass reaction container, to prepare a uniformly mixed suspension.

The ceramic substrate disperser was added into the first glass reaction container, stirred at a high speed for 3 to 5 minutes, and ultrasonically treated for 6 to 8 minutes to obtain a uniformly dispersed first suspension. In addition, the single crystal sapphire fiber disperse was added into the second glass reaction container, stirred at a high speed for 4 to 6 minutes, and ultrasonically treated for 6 to 8 minutes to obtain a uniformly dispersed second suspension.

Thirdly, the second suspension was dropwise added into the first suspension. During the dropwise addition of the second suspension, the first suspension and the second suspension were stirred at a high speed such that the two suspensions are sufficiently mixed to obtain a third suspension. The third suspension was made to stand still for 1 to 3 hours, and then the third suspension after standing still was vacuum filtered to obtain a precipitate.

The precipitate was dried at a temperature of 97° C. to 103° C. for at least 36 hours to obtain a dried mixed powder.

Finally, the mixed powder and a sintering aid (SiO₂ single-phase nano powder) was added into a graphite mold for hot-pressing sintering to obtain the ceramic-based toughness-enhanced material.

The hot-pressing sintering was carried out under a sintering temperature of 2100° C. to 2150° C., a heat preservation time of 30 to 50 minutes, and a sintering pressure of 30 to 35 MPa.

### Fourth Embodiment

Firstly, according to the volume percentage, the following starting material components were obtained: ceramic substrate powder 92%, single crystal sapphire fiber 4%, ceramic substrate disperser 0.3%, single crystal sapphire fiber disperse 0.7%, and sintering aid 3%.

Secondly, the ceramic substrate powder and the single crystal sapphire fiber were respectively added into a first glass reaction container and a second glass reaction container, to prepare a uniformly mixed suspension.

The ceramic substrate disperser was added into the first glass reaction container, stirred at a high speed for 3 to 5 minutes, and ultrasonically treated for 6 to 8 minutes to obtain a uniformly dispersed first suspension. In addition, the single crystal sapphire fiber disperse was added into the second glass reaction container, stirred at a high speed for 4 to 6 minutes, and ultrasonically treated for 6 to 8 minutes to obtain a uniformly dispersed second suspension.

Thirdly, the second suspension was dropwise added into the first suspension. During the dropwise addition of the second suspension, the first suspension and the second suspension were stirred at a high speed such that the two suspensions are sufficiently mixed to obtain a third suspension. The third suspension was made to stand still for 1 to 3 hours, and then the third suspension after standing still was vacuum filtered to obtain a precipitate.

The precipitate was dried at a temperature of 97° C. to 103° C. for at least 36 hours to obtain a dried mixed powder.

Finally, the mixed powder and a sintering aid (Al₂O₃—SiO₂ binary nano powder) was added into a graphite mold for hot-pressing sintering to obtain the ceramic-based toughness-enhanced material.

The hot-pressing sintering was carried out under a sintering temperature of 2100° C. to 2150° C., a heat preservation time of 30 to 50 minutes, and a sintering pressure of 30 to 35 MPa.

### Fifth Embodiment

Firstly, according to the volume percentage, the following starting material components were obtained: ceramic substrate powder 90%, single crystal sapphire fiber 6%, ceramic substrate disperser 0.3%, single crystal sapphire fiber disperse 0.7%, and sintering aid 3%.

Secondly, the ceramic substrate powder and the single crystal sapphire fiber were respectively added into a first glass reaction container and a second glass reaction container, to prepare a uniformly mixed suspension.

The ceramic substrate disperser was added into the first glass reaction container, stirred at a high speed for 3 to 5 minutes, and ultrasonically treated for 6 to 8 minutes to obtain a uniformly dispersed first suspension. In addition, the single crystal sapphire fiber disperse was added into the second glass reaction container, stirred at a high speed for 4 to 6 minutes, and ultrasonically treated for 6 to 8 minutes to obtain a uniformly dispersed second suspension.

Thirdly, the second suspension was dropwise added into the first suspension. During the dropwise addition of the second suspension, the first suspension and the second suspension were stirred at a high speed such that the two suspensions are sufficiently mixed to obtain a third suspension. The third suspension was made to stand still for 1 to 3 hours, and then the third suspension after standing still was vacuum filtered to obtain a precipitate.

The precipitate was dried at a temperature of 97° C. to 103° C. for at least 36 hours to obtain a dried mixed powder.

Finally, the mixed powder and a sintering aid (Al₂O₃—SiO₂—CaSO₄ ternary composite nano powder) was added into a graphite mold for hot-pressing sintering to obtain the ceramic-based toughness-enhanced material.

The hot-pressing sintering was carried out under a sintering temperature of 1800° C. to 2000° C., a heat preservation time of 30 to 50 minutes, and a sintering pressure of 30 to 35 MPa.

### Sixth Embodiment

The ceramic-based toughness-enhanced material prepared in Examples 1 to 5 and the ceramic-based material obtained by hot-pressing sintering without addition of the enhancing phase single crystal sapphire fiber were used as the control group, samples were taken for corresponding tests, and the fracture toughness, hardness and relative density of the material were analyzed and determined.

The test results of the above six samples are listed in the following table.

| | Relative density | Fracture toughness | Vickers hardness |
|---|---|---|---|
| embodiment | (%) | (MPa · m1/2) | (MPa) |
| First | 93 | 7.2 | 1022 |
| Second | 92 | 7.1 | 1007 |
| Third | 85 | 6.9 | 955 |
| Fourth | 83 | 7.0 | 1005 |
| Fifth | 90 | 7.2 | 931 |
| Control | 99 | 5.3 | 1035 |

1. As seen from comparisons between first embodiment, second embodiment and the control group, after the single crystal sapphire fiber is added as an enhancing phase, the toughness of the ceramic material is effectively improved by almost 50%, and the ceramic material has good mechanical property.

2. As seen from comparisons between first embodiment and the control group or the second embodiment and the control group, after the ratio of the additive exceeds a specific value, continuous increase of the single crystal sapphire fiber contributes less to the fracture toughness. On the contrary, the increase of the addition causes some impacts to the feature of original high hardness of the ceramic material, and the entire mechanical property of the ceramic material is degraded.

3. As seen from comparisons between first embodiment, second embodiment, third embodiment and fourth embodiment, relative to other sintering aids, the ternary composite sintering aid is capable of effectively improving the compact density of the finally sintered ceramic material.

Described above are exemplary embodiments of the present disclosure, but are not intended to limit the scope of the present disclosure. Any equivalent structure or equivalent process variation made based on the specification and drawings of the present disclosure, which is directly or indirectly applied in other related technical fields, fall within the scope of the present disclosure.

What is claimed is:

1. A ceramic-based toughness-enhanced material based on single crystal sapphire fiber, comprising the following starting materials by volume percentage:

| | |
|---|---|
| ceramic substrate powder | 92-96%; |
| single crystal sapphire fiber | 2-4%; |
| ceramic substrate disperser | 0.3-0.4%; |
| single crystal sapphire fiber disperser | 0.6-0.7%; |
| | and |
| sintering aid | 3-5%. |

2. The ceramic-based toughness-enhanced material based on single crystal sapphire fiber according to claim 1, wherein the ceramic-based toughness-enhanced material comprises the following starting materials by volume percentage:

| | |
|---|---|
| ceramic substrate powder | 92%; |
| single crystal sapphire fiber | 4%; |
| ceramic substrate disperser | 0.3%; |
| single crystal sapphire fiber disperser | 0.7%; |
| | and |
| sintering aid | 3%. |

3. The ceramic-based toughness-enhanced material based on single crystal sapphire fiber according to claim 1, wherein the ceramic-based toughness-enhanced material comprises the following starting materials by volume percentage:

| | |
|---|---|
| ceramic substrate powder | 92%; |
| single crystal sapphire fiber | 3%; |
| ceramic substrate disperser | 0.4%; |
| single crystal sapphire fiber disperser | 0.6%; |
| | and |
| sintering aid | 4%. |

4. The ceramic-based toughness-enhanced material based on single crystal sapphire fiber according to claim 1, wherein the ceramic substrate powder is magnesium oxide ceramic substrate powder, zirconium oxide ceramic substrate powder, or silicon carbide ceramic substrate powder.

5. The ceramic-based toughness-enhanced material based on single crystal sapphire fiber according to claim 1, wherein the sintering aid is AL₂O₃—SiO₂—CaSO₄ nano powder composite sintering aid distributed in a network gel.

6. The ceramic-based toughness-enhanced material based on single crystal sapphire fiber according to claim 1, wherein the ceramic substrate disperser is polyethylene glycol, and the single crystal sapphire fiber disperser is polyvinylpyrrolidone.

7. A preparation method for the ceramic-based toughness-enhanced material based on single crystal sapphire fiber comprising
weighing the ceramic substrate powder and the single crystal sapphire fiber;
adding the ceramic substrate powder into a first reaction container, and adding the single crystal sapphire into a second reaction container;
adding the ceramic substrate disperser into the first reaction container, and stirring at a high speed and carrying out ultrasonic treatment to obtain a uniformly dispersed first suspension;
adding the single crystal sapphire fiber disperser into the second reaction container, and stirring at a high speed and carrying out ultrasonic treatment to obtain a uniformly dispersed second suspension;
dropwise adding the second suspension into the first suspension, and stirring at a high speed such that the first suspension and the second suspension are sufficiently mixed to obtain a third suspension;
vacuum filtering and drying the third suspension to obtain a mixed powder; and
adding the mixed powder and the sintering aid into a graphite mold for hot-pressing sintering to obtain the ceramic-based toughness-enhanced material.

8. The preparation method according to claim 7, wherein the hot-pressing sintering is carried out under a sintering temperature of 1800° C. to 2000° C., a heat preservation time of 30 to 50 minutes, and a sintering pressure of 30 to 35 MPa.

9. The preparation method according to claim 7, wherein the vacuum filtering and drying the third suspension to obtain a mixed powder comprises:
leaving the third suspension standing still for 1 to 3 hours;
vacuum filtering the third suspension after standing still, and taking a precipitate; and
drying the precipitate at a temperature of 97° C. to 103° C. for at least 36 hours to obtain the mixed powder.
